(19) United States
(12) Patent Application Publication
(10) Pub. No.: US 2026/0040974 A1
(43) Pub. Date: Feb. 5, 2026

(54) FAN-OUT SEMICONDUCTOR PACKAGE HAVING UNDER-BUMP METALLURGY

(71) Applicant: SK hynix Inc., Icheon-si Gyeonggi-do (KR)

(72) Inventors: Kyoung Tae EUN, Icheon-si Gyeonggi-do (KR); Ki Jun SUNG, Icheon-si Gyeonggi-do (KR)

(73) Assignee: SK hynix Inc., Icheon-si Gyeonggi-do (KR)

(21) Appl. No.: 19/015,295

(22) Filed: Jan. 9, 2025

(30) Foreign Application Priority Data
Jul. 31, 2024 (KR) 10-2024-0101448

(51) Int. Cl. H01L 23/00; H01L 23/31; H01L 23/498

(52) U.S. Cl. CPC H01L 24/24; H01L 23/3142; H01L 23/49816; H01L 23/49838; H01L 2224/24226; H01L 2924/18301

(57) ABSTRACT

A semiconductor package includes a connector connected to a semiconductor chip; a first redistribution layer including a first redistribution pattern; a second redistribution layer including a second redistribution pattern; and an under-bump metallization (UBM) pad disposed on the second redistribution layer; the second redistribution pattern including a redistribution pad aligned with the UBM pad and a side surface extending beyond a side surface of the UBM pad in a first direction; the first redistribution pattern including first redistribution lines comprising a first line aligned with a first edge of the redistribution pad and a second line aligned with a second edge of the redistribution pad; a first side surface of the first line extending farther in the first direction than the first edge of the redistribution pad, and a first side surface of the second line extending farther in the first direction than the second edge of the redistribution pad.

### CROSS REFERENCE TO RELATED APPLICATION

The present application claims priority under 35 U.S.C. §119(a) to Korean Patent Application No. 10-2024-0101448 filed in the Korean Intellectual Property Office on Jul. 31, 2024, which application is incorporated herein by reference in its entirety.

### BACKGROUND

### 1. Technical Field

The present disclosure relates to semiconductor packages, including but not limited to fan-out semiconductor packages utilizing under-bump metallurgy (UBM).

### 2. Related Art

A semiconductor chip includes an integrated circuit that stores data or processes data. In addition, the semiconductor chip includes chip pads utilized to input data to the integrated circuit or output data from the integrated circuit to a device outside the semiconductor chip. A semiconductor package electrically connects the semiconductor chip to an external device. Various methods may be applied to electrically connect the chip pads. A semiconductor package using a redistribution layer has redistribution patterns that are electrically connected to the chip pads.

Among semiconductor packages using a redistribution layer, a fan-out semiconductor package employs a technology including extending redistribution patterns connected to chip pads outside of a region where a semiconductor chip is disposed, to thereby dispose external connection terminals in a region outside the semiconductor chip. The fan-out semiconductor package provides advantages in that not only the number and pitch of external connection terminals are not limited by chip size but also a standardized ball layout may be used regardless of chip size.

### SUMMARY

In an embodiment, a semiconductor package may include: a semiconductor chip; a connector connected to the semiconductor chip; a molding member sealing the semiconductor chip and the connector; a first redistribution layer disposed over the molding member and the connector, and including a first redistribution pattern and a first dielectric layer; a second redistribution layer disposed on the first redistribution layer and including a second redistribution pattern and a second dielectric layer; and a UBM pad disposed on the second redistribution layer. The second redistribution pattern includes a redistribution pad aligned with the UBM pad in a third direction and has a side surface that extends beyond a side surface of the UBM pad in a first direction; the first redistribution pattern includes a plurality of first redistribution lines comprising a first line and a second line, extending in a second direction perpendicular to the first direction, a first edge of the redistribution pad aligned in the third direction with the first line and a second edge of the redistribution pad aligned in the third direction with the second line; a first side surface of the first line faces opposite in the first direction to a second side surface of the first line, and a first side surface of the second line faces opposite in the first direction to a second side surface of the second line; the second side surface of the first line and the second surface of the second line are disposed in partial alignment with the redistribution pad in the third direction, the first side surface of the first line extends farther in the first direction from a center of the UBM pad than the first edge of the redistribution pad extends from the center of the UBM pad, and the first side surface of the second line extends farther in the first direction from a center of the UBM pad than the second edge of the redistribution pad extends from the center of the UBM pad.

In an embodiment, a semiconductor package may include: a semiconductor chip; a connector connected to the semiconductor chip; a molding member sealing the semiconductor chip and the connector; a first redistribution layer disposed over the molding member and the connector, and including a first redistribution pattern and a first dielectric layer; a second redistribution layer disposed on the first redistribution layer and including a second redistribution pattern and a second dielectric layer; and a UBM pad disposed on the second redistribution layer. The second redistribution pattern includes a redistribution pad that aligns with the UBM pad in a third direction and has an area larger than an area of the UBM pad; the first redistribution pattern includes a plurality of first redistribution lines comprising a first line and a second line, extending in a second direction perpendicular to a first direction, a first edge of the redistribution pad aligned in the third direction with the first line and a second edge of the redistribution pad aligned in the third direction with the second line; a first side surface of the first line faces opposite in the first direction to a second side surface of the first line, and a first side surface of the second line faces opposite in the first direction to a second side surface of the second line, the first side surface of the first line is located farther away from a center of the UBM pad in the first direction than a second side surface of the first line is located with respect to the center of the UBM pad in the first direction; and a distance between first side surface of the first line and the first side surface of the second line is larger than a measurement of the redistribution pad in the first direction.

A semiconductor package comprising a semiconductor chip; a connector connected to the semiconductor chip; a first redistribution layer disposed over the connector and including a first redistribution pattern; a second redistribution layer disposed on the first redistribution layer and including a second redistribution pattern; and an under-bump metallization (UBM) pad disposed on the second redistribution layer; wherein the second redistribution pattern includes a redistribution pad aligned with the UBM pad in a third direction and extends beyond a side surface of the UBM pad in a first direction; and wherein the first redistribution pattern extends in the first direction farther from a center of the UBM pad than the side surface of the redistribution pad extends from the center of the UBM pad.

### BRIEF DESCRIPTION OF THE DRAWINGS

FIG. 1 is a cross-sectional view of a semiconductor package according to an embodiment of the present disclosure.

FIG. 2 is an enlarged view of section A of FIG. 1 according to an embodiment of the present disclosure.

FIG. 3 is a plan view corresponding to section A of FIG. 1 according to an embodiment of the present disclosure.

FIG. 4 is a cross-sectional view illustrating a semiconductor package according to an embodiment of the present disclosure.

FIG. 5 is a cross-sectional view of a semiconductor package according to an embodiment of the present disclosure.

FIG. 6 is an enlarged cross-sectional view of section C of FIG. 5 according to an embodiment of the present disclosure.

FIG. 7 is a cross-sectional view illustrating a semiconductor package according to an embodiment of the present disclosure.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” or “under,” another element, the elements may directly contact each other or an intervening element may be disposed between the elements.

Terms such as “vertical,” “horizontally,” “top,” “bottom,” “above,” “below,” “under,” “over,” “on,” “side,” “upper,” “lower,” “front,” “left,” “right,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

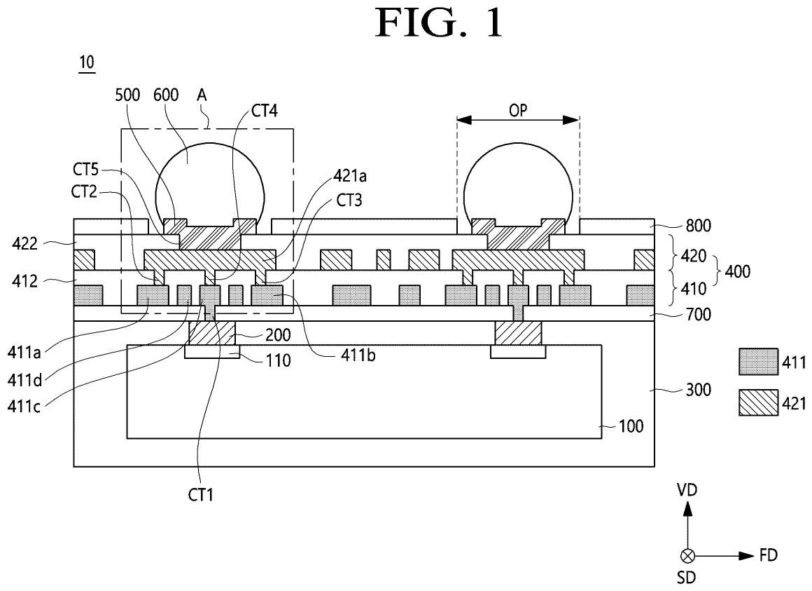

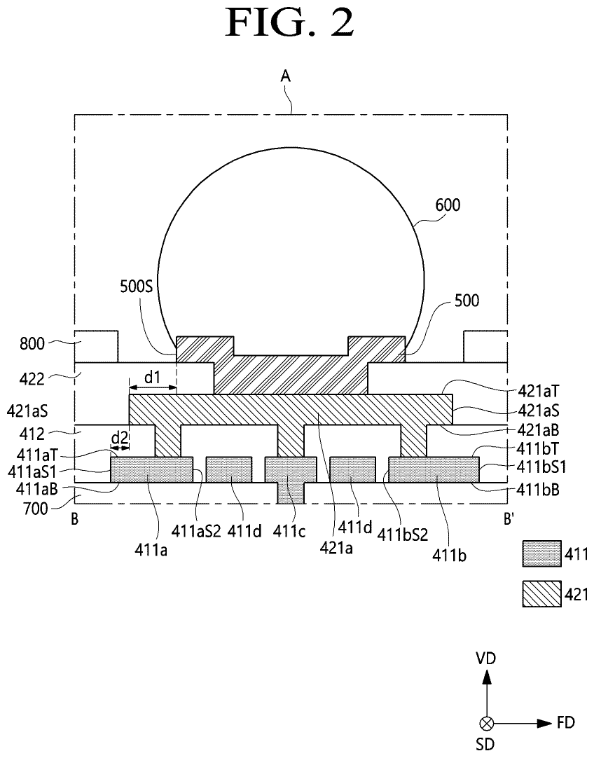

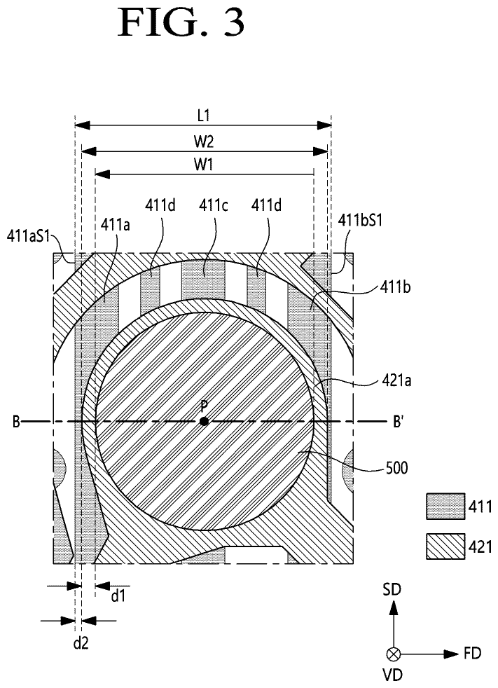

FIG. 1 is a cross-sectional view of a semiconductor package according to an embodiment of the present disclosure, FIG. 2 is an enlarged view of section A of FIG. 1, and FIG. 3 is a plan view corresponding to section A of FIG. 1. FIG. 2 is a cross-sectional view taken along a line B-B′ of FIG. 3, and the line B-B′ traverses a center P of a UBM pad 500 in a first direction FD.

A second direction SD is a direction in which first redistribution lines 411a and 411b extend as shown in FIG. 3, the first direction FD is a direction that extends horizontally with respect to the drawing of FIG. 1 and is orthogonal or perpendicular to the second direction SD, and a third direction referred to as a vertical direction VD, extends vertically with respect to the drawing of FIG. 1 and is orthogonal or perpendicular to the first direction FD and the second direction SD.

Referring to FIG. 1, a semiconductor package 10 according to an embodiment of the present disclosure includes a semiconductor chip 100, a connector 200, a molding member 300, a redistribution structure 400, a UBM pad 500, and an external connection terminal 600.

The semiconductor chip 100 has a chip pad 110 on a front surface. The chip pad 110 may be disposed at an edge of the semiconductor chip 100. The semiconductor chip 100 may have an edge pad type structure. Although FIG. 1 illustrates chip pads 110 disposed at the edge of the semiconductor chip 100, the present disclosure is not limited to this example.

An integrated circuit (not illustrated) including cell transistors is integrated in the semiconductor chip 100. The chip pad 110 is electrically connected to the integrated circuit through a wiring pattern (not illustrated) inside the semiconductor chip 100. The chip pad 110 is provided as a connection terminal that electrically connects the semiconductor chip 100 to an external device.

The semiconductor chip 100 may include nonvolatile memory such as NAND, NOR, PRAM (phase change random access memory) and MRAM (magnetoresistive random access memory), volatile memory such as DRAM (dynamic random access memory) and SRAM (static random access memory), and a processor such as a CPU (central processing unit), a GPU (graphics processing unit), an AP (application processor), and an NPU (neural processing unit).

A connector 200 is disposed on a top surface of the semiconductor chip 100. The connector 200 includes an interconnection member that extends substantially in the vertical direction VD from the top surface of the semiconductor chip 100 or is constructed substantially in the vertical direction VD.

The connector 200 extends in the vertical direction VD with a first end connected to the chip pad 110 of the semiconductor chip 100. The connector 200 provides a path through which an electrical signal is connected to the semiconductor chip 100. The connector 200 may include a bonding wire, a conductive bump, or a conductive pillar. The connector 200 may include a metal. The metal may include gold (Au), copper (Cu), silver (Ag) or platinum (Pt).

The molding member 300 covers the semiconductor chip 100 and the connector 200. The molding member 300 seals the semiconductor chip 100 and the connector 200 to protect the semiconductor chip 100 and the connector 200 from an external environment. The molding member 300 may include an encapsulant material. The encapsulant material may include an epoxy molding compound (EMC). The epoxy molding compound may include resin and fillers.

A second end of the connector 200 opposite to the first end of the connector 200 connected to the semiconductor chip 100 is exposed adjacent to a first surface of the molding member 300, such as the upper surface of the molding member 300 relative to FIG. 1.

An insulating layer 700 is disposed on the first surface of the molding member 300 and the connector 200. The insulating layer 700 covers the first surface of the molding member 300 and the second end of connector 200. The insulating layer 700 electrically isolates a first redistribution pattern 411 from the connector 200. The insulating layer 700 may include a polymer-based dielectric material. In an embodiment, the insulating layer 700 is not included.

The redistribution structure 400 is disposed on the insulating layer 700. The redistribution structure 400 includes a first redistribution layer 410 disposed on the insulating layer 700 and a second redistribution layer 420 disposed on the first redistribution layer 410.

The first redistribution layer 410 includes a first redistribution pattern 411 and a first dielectric layer 412.

The first redistribution pattern 411 is disposed on the insulating layer 700. The first redistribution pattern 411 includes a pair of first redistribution lines 411a and 411b disposed below a redistribution pad 421a in the vertical direction VD. Each edge of the redistribution pad 421a is disposed over one of the first redistribution lines 411a and 411b in the vertical direction VD. Each edge of the redistribution pad 421a may overlap one of the first redistribution lines 411a and 411b. The pair of first redistribution lines 411a and 411b include a left first redistribution line 411a and a right first redistribution line 411b. The left edge of the redistribution pad 421a is disposed above the left first redistribution line 411a in the vertical direction VD. The left edge of the redistribution pad 421a may overlap the left first redistribution line 411a. The right edge of the redistribution pad 421a is disposed above the right first redistribution line 411b in the vertical direction VD. The right edge of the redistribution pad 421a may overlap the right first redistribution line 411b.

The first redistribution pattern 411 includes a first additional redistribution line 411c and a second additional redistribution line 411d that are disposed between the left first redistribution line 411a and the right first redistribution line 411b. The additional redistribution lines 411c and 411d extend in the second direction SD. The additional redistribution lines 411c and 411d are disposed below the redistribution pad 421a in the vertical direction VD. The additional redistribution lines 411c and 411d may overlap the redistribution pad 421a.

The first additional redistribution line 411c includes a first contact section CT1 connected to the connector 200 and extending through the insulating layer 700. The first additional redistribution line 411c is connected to the connector 200. The first additional redistribution line 411c is electrically connected to the chip pad 110 of the semiconductor chip 100 through the connector 200. The second additional redistribution line 411d is not electrically connected to the connector 200.

Although FIG. 1 illustrates that the first redistribution pattern 411 includes the first additional redistribution line 411c and the second additional redistribution line 411d, the present disclosure is not limited to this example. In an embodiment, the first redistribution pattern 411 includes one of the first additional redistribution line 411c and the second additional redistribution line 411d.

The first dielectric layer 412 is disposed on the insulating layer 700 and the first redistribution pattern 411. The first dielectric layer 412 covers the insulating layer 700 and the first redistribution pattern 411. The first dielectric layer 412 may electrically isolate the left first redistribution line 411a, the right first redistribution line 411b and the additional redistribution lines 411c and 411d from each other. The first dielectric layer 412 may electrically isolate a second redistribution pattern 421 from the first redistribution pattern 411.

The second redistribution layer 420 includes the second redistribution pattern 421 and a second dielectric layer 422.

The second redistribution pattern 421 is disposed on the first dielectric layer 412. The second redistribution pattern 421 includes the redistribution pad 421a that is disposed below the UBM pad 500 in the vertical direction VD.

The redistribution pad 421a includes second contact section CT2, third contact section CT3, and fourth contact section CT4. The second contact section CT2 is connected to the left first redistribution line 411a. The second contact section CT2 passes through the first dielectric layer 412. The third contact section CT3 is connected to the right first redistribution line 411b and passes through the first dielectric layer 412. The fourth contact section CT4 is connected to the first additional redistribution line 411c by passing through the first dielectric layer 412. The redistribution pad 421a is connected to the first additional redistribution line 411c. The redistribution pad 421a is electrically connected to the chip pad 110 of the semiconductor chip 100 through the connector 200. Although not illustrated, the first redistribution lines 411a and 411b are electrically connected to chip pads of the semiconductor chip 100 via connectors.

The second dielectric layer 422 is disposed on the first dielectric layer 412 and the second redistribution pattern 421. The second dielectric layer 422 covers the first dielectric layer 412 and the second redistribution pattern 421. The second dielectric layer 422 electrically isolates the UBM pad 500 from some of the elements of the second redistribution pattern 421.

The UBM pad 500 is disposed on the second dielectric layer 422. The UBM pad 500 is coupled to the external connection terminal 600.

The UBM pad 500 includes a fifth contact section CT5 connected to the redistribution pad 421a. The UBM pad 500 passes through the second dielectric layer 422. The UBM pad 500 is connected to the redistribution pad 421a. The UBM pad 500 is electrically connected to the chip pad 110 of the semiconductor chip 100 through the first additional redistribution line 411c and the connector 200.

A passivation layer 800 is formed with an opening OP that exposes the UBM pad 500. The passivation layer 800 is disposed on the second redistribution layer 420. The passivation layer 800 protects the second redistribution layer 420. The passivation layer 800 may include polyimide (PI), Polybenzoxazole (PBO), BCB (benzocyclobutene), and PHS (Poly Hydroxystylene). In an embodiment, the passivation layer 800 covers the UBM pad 500 such that only a small area of the UBM pad 500 is exposed.

An area of the opening OP in the first direction FD and the second direction SD is larger than an area of the UBM pad 500 in the first direction FD and the second direction SD. A small region of the second dielectric layer 422 near or surrounding the UBM pad 500 is not covered with the passivation layer 800 in this example. The edge of the UBM pad 500 is spaced apart from the passivation layer 800. The passivation layer 800 does not contact the UBM pad 500 in the example of FIG. 1. The UBM pad 500 may be a non-solder mask defined (NSMD) type structure.

The external connection terminal 600 is disposed on the UBM pad 500. The external connection terminal 600 may be a solder ball.

A region where the external connection terminal 600 lands may be identified by the measurements of the UBM pad 500 in the first direction FD and the second direction SD. The measurements of the external connection terminal 600 may be larger than the measurements of the UBM pad 500.

The thermal expansion coefficient of the redistribution patterns 411 and 421 and the UBM pad 500 is different from the thermal expansion coefficient of the dielectric layers 412 and 422. The thermal expansion coefficient of the redistribution patterns 411 and 421 and the UBM pad 500 is lower or smaller than the thermal expansion coefficient of the dielectric layers 412 and 422. The redistribution patterns 411 and 421 and the UBM pad 500 may include metal, and the dielectric layers 412 and 422 may include a polymer-based dielectric material.

Referring to FIG. 2 and FIG. 3, the redistribution pad 421a is disposed under the UBM pad 500 in the vertical direction VD. The redistribution pad 421a may overlap the UBM pad 500. The redistribution pad 421a has a region that extends beyond the UBM pad 500 in the first direction FD and the second direction SD. The entirety of the UBM pad 500 is disposed over the redistribution pad 421a in the vertical direction VD in this example. The redistribution pad 421a extends beyond the UBM pad 500 in the first direction FD and the second direction SD and has a larger area than the area of the UBM pad 500 in the first direction FD and the second direction SD.

The redistribution pad 421a has a top surface 421aT, a bottom surface 421aB, and a side surface 421aS between the top surface 421aT and the bottom surface 421aB. The side surface 421aS of the redistribution pad 421a extends by d1 beyond a side surface 500S of the UBM pad 500 in the first direction FD. The UBM pad 500 has a width W1 in the first direction FD. The redistribution pad 421a has a width W2 in the first direction FD. W2 is wider or larger than W1 as shown in FIG. 3.

The left first redistribution line 411a has a top surface 411aT, a bottom surface 411aB, and a first side surface 411aS1, and a second side surface 411aS2. The first side surface 411aS1 and the second side surface 411aS2 are between the top surface 411aT and the bottom surface 411aB and face in opposite directions along the first direction FD. The first side surface 411aS1 of the left first redistribution line 411a is disposed farther away in the first direction FD from the center P of the UBM pad 500 than the second side surface 411aS2 of the left first redistribution line 411a is disposed from the center P of the UBM pad 500.

As viewed from the cross section taken along the line B-B′, the second side surface 411aS2 of the left first redistribution line 411a is disposed under the redistribution pad 421a in the vertical direction VD. The second side surface 411aS2 of the left first redistribution line 411a may overlap the redistribution pad 421a. The first side surface 411aS1 of the left first redistribution line 411a extends by d2 in the first direction FD beyond the left side surface 421aS of the redistribution pad 421a in a direction away from the center of the UBM pad 500.

The right first redistribution line 411b has a top surface 411bT, a bottom surface 411bB, a first side surface 411bS1, and a second side surface 411bS2. The first side surface 411bS1 and the second side surface 411bS2 are between the top surface 411bT and the bottom surface 411bB and face in opposite directions along the first direction FD. The first side surface 411bS1 of the right first redistribution line 411b is disposed farther away in the first direction FD from the center P of the UBM pad 500 than the second side surface 411bS2 of the right first redistribution line 411b is disposed from the center P of the UBM pad 500.

As viewed from the cross section taken along the line B-B′,

the second side surface 411bS2 of the right first redistribution line 411b is disposed below the redistribution pad 421a in the vertical direction VD. The second side surface 411bS2 of the right first redistribution line 411b may overlap the redistribution pad 421a. The first side surface 411bS1 of the right first redistribution line 411b extends in the first direction FD beyond the right side surface 421aS of the redistribution pad 421a in a direction away from the center of the UBM pad 500.

The redistribution pad 421a has a width W2 in the first direction FD. A distance between the first side surface 411aS1 of the left first redistribution line 411a and the first side surface 411bS1 of the right first redistribution line 411b is L1 that is a larger than width W2.

Various materials are used in a semiconductor package. For example, a redistribution pattern may be made of metal, and a dielectric layer may include a polymer-based dielectric material. When the semiconductor package is subject to thermal changes, thermal stress may occur due to differences in thermal expansion coefficient between different materials in the semiconductor package. Such thermal stress may cause a defect such as delamination between the different materials and/or a crack in the materials. For example, thermal stress may be concentrated at the boundary between the side surface of the redistribution pattern and the dielectric layer. When the side surface of an upper redistribution pattern is vertically aligned with the side surface of a lower redistribution pattern, the stress generated at the boundary between the side surface of the upper redistribution pattern and the dielectric layer and the stress generated at the boundary between the side surface of the lower redistribution pattern and the dielectric layer may be added or combined together, increasing the intensity of stress and aggravating or increasing a defect.

According to an embodiment of the present disclosure, because the side surface 421aS of the redistribution pad 421a is configured to extend further than the side surface 500S of the UBM pad 500 in the first direction FD, the side surface 421aS of the redistribution pad 421a is not aligned with the side surface 500S of the UBM pad 500 in the vertical direction VD. Thus, the stress generated at the boundary between the side surface 421aS of the redistribution pad 421a and the second dielectric layer 422 and the stress generated at the boundary between the side surface 500S of the UBM pad 500 and the second dielectric layer 422 can be prevented from adding up. Thereby it is possible to inhibit the increase in stress intensity.

Because the first side surface 411aS1 of the left first redistribution line 411a is configured to extend further than the side surface 421aS of the redistribution pad 421a in the first direction FD, the first side surface 411aS1 of the left first redistribution line 411a is not vertically aligned with the side surface 421aS of the redistribution pad 421a. Thus, the stress generated at the boundary between the first side surface 411aS1 of the left first redistribution line 411a and the first dielectric layer 412 and the stress generated at the boundary between the side surface 421aS of the redistribution pad 421a and the second dielectric layer 422 can be prevented from adding up. Thereby it is possible to inhibit the increase in stress intensity. Because the first side surface 411bS1 of the right first redistribution line 411b is configured to extend further than the side surface 421aS of the redistribution pad 421a in the first direction FD, the first side surface 411bS1 of the right first redistribution line 411b is not vertically aligned with the side surface 421aS of the redistribution pad 421a. Thus, the stress generated at the boundary between the first side surface 411bS1 of the right first redistribution line 411b and the first dielectric layer 412 and the stress generated at the boundary between the side surface 421aS of the redistribution pad 421a and the second dielectric layer 422 can be prevented from adding up. Thereby it is possible to inhibit the increase in stress intensity.

Because the redistribution pad 421a is aligned with the UBM pad 500 in the vertical direction VD and extends beyond the outer edges of the UBM pad 500 in the first direction FD, thermal stress and cracks resulting from thermal stress may be prevented from propagating downward.

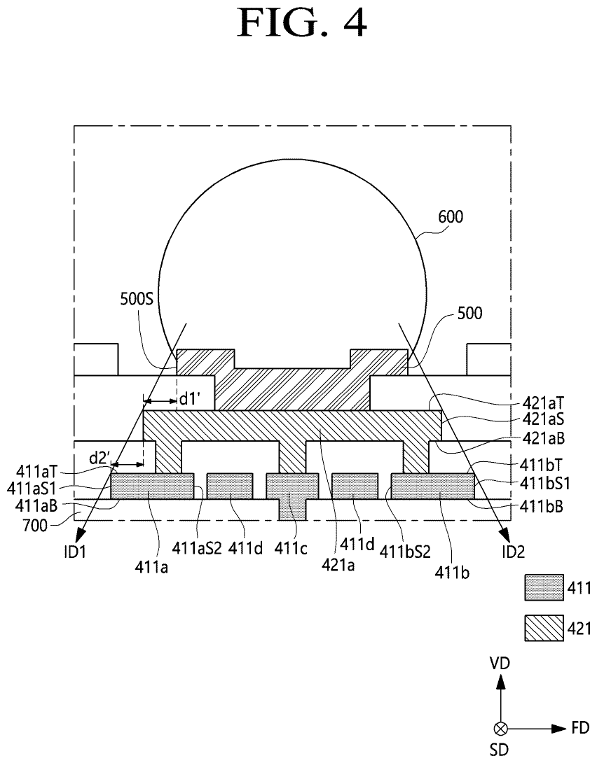

FIG. 4 is a cross-sectional view of a semiconductor package, according to an embodiment of the present disclosure, illustrating a cross-section taken along a line traversing the center of the UBM pad 500 in the first direction FD.

Referring to FIG. 4, the side surface 500S of the UBM pad 500, the side surface 421aS of the redistribution pad 421a, and the first side surface 411aS1 of the left first redistribution line 411a are disposed along a first line ID1 oblique to the vertical direction VD and the first direction FD.

The side surface 500S of the UBM pad 500, the side surface 421aS of the redistribution pad 421a and the first side surface 411bS1 of the right first redistribution line 411b are disposed along a second line ID2 oblique to the vertical direction VD and the first direction FD.

The side surface 421aS of the redistribution pad 421a extends by d1′ in the first direction beyond the side surface 500S of the

UBM pad 500. The first side surface 411aS1 of the left first redistribution line 411a protrudes extends the first direction FD by d2′ beyond the left side surface 421aS of the redistribution pad 421a. The first side surface 411bS1 of the right first redistribution line 411b extends in the first direction FD by d2′ beyond the right side surface 421aS of the redistribution pad 421a.

The d1′ may be equal to d2′. In an embodiment, the sizes of d1′ and d2′ may be the same as a minimum width of the first and second redistribution patterns 411 and 421. The minimum width of the first and second redistribution patterns 411 and 421 may be determined by process capability such as the resolution limit of a patterning process.

The measurement of the redistribution pad 421a in the first direction FD may be larger, by two times the minimum width of the first and second redistribution patterns 411 and 421, than the measurement of the UBM pad 500 in the first direction FD.

The minimum distance between the first side surface 411aS1 of the left first redistribution line 411a and the first side surface 411bS1 of the right first redistribution line 411b may be larger by two times the minimum width of the first and second redistribution patterns 411 and 421 than the measurement of the redistribution pad 421 in the first direction FD.

Suppressing the concentration of thermal stress may be achieved using larger values of d1′ and d2′. Increasing the measurements of the redistribution pad 421a to increase the size of d1′ may limit the placement of other elements included in the second redistribution pattern 421. In addition, increasing the width of the first redistribution lines 411a and 411b to increase the size of d2′ may limit the placement of other elements included in the first redistribution pattern 411.

By configuring d1′ and d2′ to have the same size as the minimum width of the first and second redistribution patterns 411 and 421, layout constraints may be reduced while suppressing stress concentration.

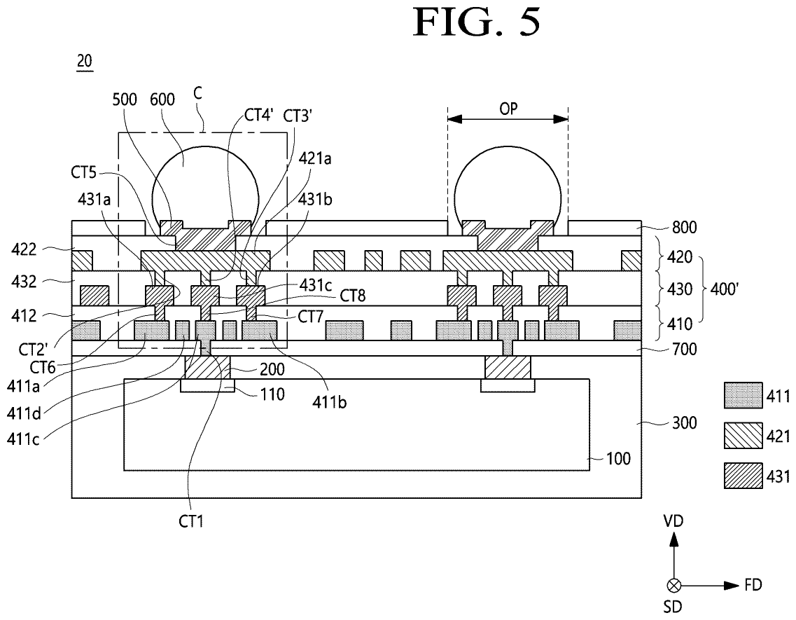

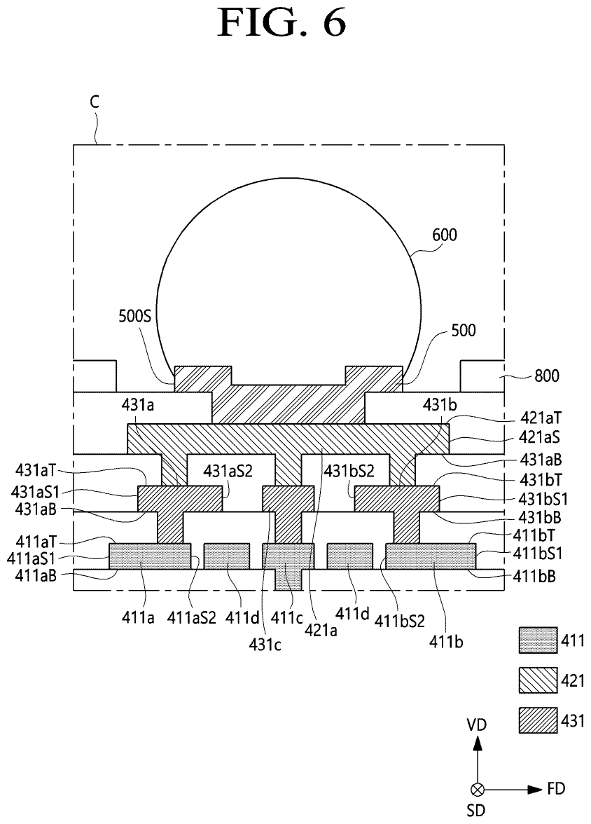

FIG. 5 is a cross-sectional view of a semiconductor package according to an embodiment of the present disclosure, and FIG. 6 is an enlarged cross-sectional view of section C of FIG. 5.

Referring to FIG. 5, a redistribution structure 400′ of a semiconductor package 20 includes the first redistribution layer 410, the second redistribution layer 420, and a third redistribution layer 430 between the first redistribution layer 410 and the second redistribution layer 420.

The redistribution structure 400′ of FIG. 5 includes the first redistribution layer 410 and the second redistribution layer 420 similar to the redistribution structure 400 described with reference to FIG. 1 to FIG. 4.

The third redistribution layer 430 includes a third redistribution pattern 431 and a third dielectric layer 432.

The third redistribution pattern 431 is disposed on the first dielectric layer 412. The third redistribution pattern 431 includes a pair of second redistribution lines 431a and 431b. The pair of second redistribution lines 431a and 431b includes a left second redistribution line 431a and a right second redistribution line 431b.

The left second redistribution line 431a extends in the second direction SD. The left second redistribution line 431a is partially disposed over the left first redistribution line 411a in the vertical direction VD. The left second redistribution line 431a may partially overlap the left first redistribution line 411a. The right second redistribution line 431b extends in the second direction SD. The right second redistribution line 431b is partially disposed over the right first redistribution line 411b in the vertical direction VD. The right second redistribution line 431b may partially overlap the right first redistribution line 411b.

The third redistribution pattern 431 further includes a third additional redistribution line 431c that is disposed between the left second redistribution line 431a and the right second redistribution line 431b. The third additional redistribution line 431c extends in the second direction SD between the left second redistribution line 431a and the right second redistribution line 431b. The third additional redistribution line 431c is disposed over the first additional redistribution line 411c in the vertical direction VD. The third additional redistribution line 431c may overlap the first additional redistribution line 411c.

The left second redistribution line 431a includes a sixth contact section CT6. The sixth contact section CT6 is connected to the left first redistribution line 411a. The sixth contact section CT6 passes through the first dielectric layer 412. The right second redistribution line 431b includes a seventh contact section CT7. The seventh contact section CT7 is connected to the right first redistribution line 411b. The seventh contact section CT7 passes through the first dielectric layer 412. The third additional redistribution line 431c includes an eighth contact section CT8. The eighth contact section CT8 is electrically connected to the first additional redistribution line 411c by passing through the first dielectric layer 412. The third additional redistribution line 431c is connected to the first additional redistribution line 411c. The third additional redistribution line 431c is electrically connected to the chip pad 110 of the semiconductor chip 100 through the connector 200.

The third dielectric layer 432 is disposed on the first dielectric layer 412 and the third redistribution pattern 431. The third dielectric layer 432 covers the first dielectric layer 412 and the third redistribution pattern 431. The third dielectric layer 432 electrically isolates the left second redistribution line 431a, the right second redistribution line 431b, and the third additional redistribution line 431c from each other. The third dielectric layer 432 electrically isolates some elements of the second redistribution pattern 421 from the third redistribution pattern 431.

The second redistribution pattern 421 is disposed on the third dielectric layer 432. The redistribution pad 421a of the second redistribution pattern 421 includes a second contact section CT2′, a third contact section CT3′, and a fourth contact section CT4′ that pass through the third dielectric layer 432. The second contact section CT2′ is connected to the left second redistribution line 431a. The second contact section CT2′ passes through the third dielectric layer 432. The third contact section CT3′ is connected to the right second redistribution line 431b. The third contact section CT3′ passes through the third dielectric layer 432. The fourth contact section CT4′ is connected to the third additional redistribution line 431c. The fourth contact section CT4′ passes through the third dielectric layer 432. The redistribution pad 421a is connected to the third additional redistribution line 431c. The redistribution pad 421a is electrically connected to the chip pad 110 of the semiconductor chip 100 through the first additional redistribution line 411c and the connector 200.

The second dielectric layer 422 is disposed on the third dielectric layer 432 and the second redistribution pattern 421. The second dielectric layer 422 covers the third dielectric layer 432 and the second redistribution pattern 421.

The UBM pad 500 is disposed on the second dielectric layer 422. The UBM pad 500 includes the fifth contact section CT5 that passes through the second dielectric layer 422. The fifth contact section CT5 is connected to the redistribution pad 421a, passes through the second dielectric layer 422. The fifth contact section CT5 is electrically connected to the chip pad 110 of the semiconductor chip 100 through the third additional redistribution line 431c, the first additional redistribution line 411c, and the connector 200.

The thermal expansion coefficient of the redistribution patterns 411, 421, and 431 and the UBM pad 500 is different from the thermal expansion coefficient of the dielectric layers 412, 422, and 432. The thermal expansion coefficient of the redistribution patterns 411, 421, and 431 and the UBM pad 500 is lower or smaller than the thermal expansion coefficient of the dielectric layers 412, 422, and 432. The redistribution patterns 411, 421, and 431 and the UBM pad 500 may include metal, and the dielectric layers 412, 422, and 432 may include a polymer-based dielectric material.

Referring to FIG. 6, the redistribution pad 421a is disposed under the UBM pad 500 in the vertical direction VD. The redistribution pad 421a may overlap the UBM pad 500. The redistribution pad 421a has a region that extends beyond the UBM pad 500 in the in the first direction FD and the second direction SD. The entirety of the UBM pad 500 is disposed over the redistribution pad 421a in the vertical direction VD in this example. The redistribution pad 421a extends beyond the UBM pad 500 in the first direction FD and the second direction SD. The redistribution pad 421a has a larger area than the area the UBM pad 500 in the first direction FD and the second direction SD. The side surface 421aS of the redistribution pad 421a extends beyond the side surface 500S of the UBM pad 500 in the first direction FD.

The left second redistribution line 431a has a top surface 431aT, a bottom surface 431aB, a first side surface 431aS1, and a second side surface 431aS2. The first side surface 431aS1 and the second side surface 431aS2 are between the top surface 431aT and the bottom surface 431aB. The first side surface 431aS1 and the second side surface 431aS2 face in opposite directions along the first direction FD. The first side surface 431aS1 of the left second redistribution line 431a is disposed farther away in the first direction FD from the center of the UBM pad 500 than the second side surface 431aS2 of the left second redistribution line 431a is disposed from the center P of the UBM pad 500.

The left first redistribution line 411a is partially disposed below the left second redistribution line 431a in the vertical direction VD. The left first redistribution line 411a may overlap the left second redistribution line 431a. The second side surface 411aS2 of the left first redistribution line 411a is disposed under the left second redistribution line 431a in the vertical direction VD. The second side surface 411aS2 of the left first redistribution line 411a may overlap the left second redistribution line 431a. The first side surface 411aS1 of the left first redistribution line 411a extends in the first direction FD beyond the first side surface 431aS1 of the left second redistribution line 431a and the left side surface 421aS of the redistribution pad 421a in a direction away from the center of the UBM pad 500.

The right second redistribution line 431b has a top surface 431bT, a bottom surface 431bB, a first side surface 431bS1, and a second side surface 431bS2. The first side surface 431bS1 and the second side surface 431bS2 are between the top surface 431bT and the bottom surface 431bB. The first side surface 431bS1 and the second side surface 431bS2 face in opposite directions along the first direction FD. The first side surface 431bS1 of the right second redistribution line 431b is disposed farther away in the first direction FD from the center of the UBM pad 500 than the second side surface 431bS2 of the right second redistribution line 431b is disposed from the center P of the UBM pad 500.

The right first redistribution line 411b is partially disposed below the right second redistribution line 431b in the vertical direction VD. The right first redistribution line 411b may overlap the right second redistribution line 431b. The second side surface 411bS2 of the right first redistribution line 411b is disposed below the right second redistribution line 431b in the vertical direction VD. The second side surface 411bS2 of the right first redistribution line 411b may overlap the right second redistribution line 431b. The first side surface 411bS1 of the right first redistribution line 411b extends in the first direction FD beyond the first side surface 431bS1 of the right second redistribution line 431b and the right side surface 421aS of the redistribution pad 421a in a direction away from the center of the UBM pad 500. The distance between the first side surface 411aS1 of the

left first redistribution line 411a and the first side surface 411bS1 of the right first redistribution line 411b is larger than the distance between the first side surface 431aS1 of the left second redistribution line 431a and the first side surface 431bS1 of the right second redistribution line 431b. The distance between the first side surface 411aS1 of the left first redistribution line 411a and the first side surface 411bS1 of the right first redistribution line 411b is larger than the measurement of the redistribution pad 421a in the first direction FD.

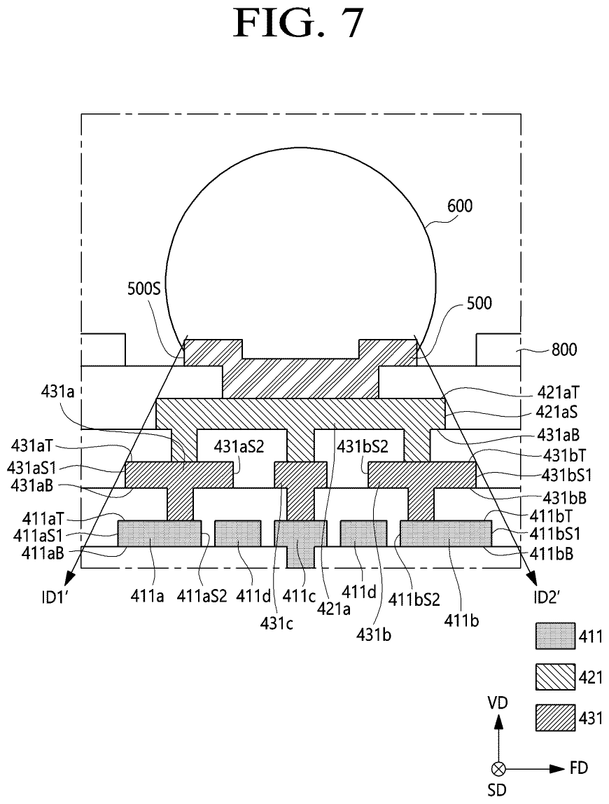

FIG. 7 is a cross-sectional view of a semiconductor package, according to an embodiment of the present disclosure, illustrating a cross-section taken along a line traversing the center of the UBM pad 500 in the first direction FD.

Referring to FIG. 7, the side surface 500S of the UBM pad 500, the side surface 421aS of the redistribution pad 421a, the first side surface 431aS1 of the left second redistribution line 431a, and the first side surface 411aS1 of the left first redistribution line 411a are disposed along a line ID1′ oblique to the vertical direction VD and the first direction FD.

The side surface 500S of the UBM pad 500, the side surface 421aS of the redistribution pad 421a, the first side surface 431bS1 of the right second redistribution line 431b, and the first side surface 411bS1 of the right first redistribution line 411b are disposed along a second line ID2′ oblique to the vertical direction VD and the first direction FD.

The distance by which the side surface 421aS of the redistribution pad 421a extends beyond the side surface 500S of the UBM pad 500 may be the same as the minimum width of the redistribution patterns 411, 421, and 431. The measurement of the redistribution pad 421a in the first direction FD may be larger by two times the minimum width of the redistribution patterns 411, 421, and 431 than the dimension in the first direction FD of the UBM pad 500.

The first side surface 431aS1 of the left second redistribution line 431a extends in the first direction FD beyond the left side surface 421aS of the redistribution pad 421a. The distance by which the first side surface 431aS1 of the left second redistribution line 431a extends beyond the side surface 421aS of the redistribution pad 421a may be the same as the minimum width of the redistribution patterns 411, 421, and 431.

The first side surface 431bS1 of the right second redistribution line 431b extends in the first direction FD beyond the right side surface 421aS of the redistribution pad 421a. The distance by which the first side surface 431bS1 of the right second redistribution line 431b extends beyond the side surface 421aS of the redistribution pad 421a may be the same as the minimum width of the redistribution patterns 411, 421, and 431.

The distance between the first side surface 431aS1 of the left second redistribution line 431a and the first side surface 431bS1 of the right second redistribution line 431b is larger than the measurement in the first direction FD of the redistribution pad 421a. The distance between the first side surface 431aS1 of the left second redistribution line 431a and the first side surface 431bS1 of the right second redistribution line 431b may be larger by two times the minimum width of the redistribution patterns 411, 421, and 431 than the measurement of the redistribution pad 421a in the first direction FD.

The first side surface 411aS1 of the left first redistribution line 411a extends in the first direction FD beyond the first side surface 431aS1 of the left second redistribution line 431a. The distance by which the first side surface 411aS1 of the left first redistribution line 411a extends beyond the first side surface 431aS1 of the left second redistribution line 431a may be the same as the minimum width of the redistribution patterns 411, 421, and 431.

The first side surface 411bS1 of the right first redistribution line 411b extends in the first direction FD beyond the first side surface 431bS1 of the right second redistribution line 431b. The distance by which the first side surface 411bS1 of the right first redistribution line 411b extends beyond the first side surface 431bS1 of the right second redistribution line 431b may be the same as the minimum width of the redistribution patterns 411, 421, and 431.

The distance between the first side surface 411aS1 of the left first redistribution line 411a and the first side surface 411bS1 of the right first redistribution line 411b is larger than the distance between the first side surface 431aS1 of the left second redistribution line 431a and the first side surface 431bS1 of the right second redistribution line 431b. The distance between the first side surface 411aS1 of the left first redistribution line 411a and the first side surface 411bS1 of the right first redistribution line 411b may be larger by two times the minimum width of the redistribution patterns 411, 421, and 431 than the distance between the first side surface 431aS1 of the left second redistribution line 431a and the first side surface 431bS1 of the right second redistribution line 431b.

Although the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

1. A semiconductor package comprising:
a semiconductor chip;
a connector connected to the semiconductor chip;
a molding member over the semiconductor chip and surrounding the connector;
a first redistribution layer disposed over the molding member and the connector and including a first redistribution pattern and a first dielectric layer;
a second redistribution layer disposed on the first redistribution layer and including a second redistribution pattern and a second dielectric layer; and
an under-bump metallurgy (UBM) pad disposed on the second redistribution layer;
wherein the second redistribution pattern includes a redistribution pad aligned with the UBM pad in a third direction and has a side surface that extends beyond a side surface of the UBM pad in a first direction;
wherein the first redistribution pattern includes a plurality of first redistribution lines comprising a first line and a second line, extending in a second direction perpendicular to the first direction and the third direction, a first edge of the redistribution pad aligned in the third direction with the first line and a second edge of the redistribution pad aligned in the third direction with the second line;
wherein a first side surface of the first line faces opposite in the first direction to a second side surface of the first line, and a first side surface of the second line faces opposite in the first direction to a second side surface of the second line; and
wherein the second side surface of the first line and the second side surface of the second line are disposed in partial alignment with the redistribution pad in the third direction, the first side surface of the first line extends farther in the first direction from a center of the UBM pad than the first edge of the redistribution pad extends from the center of the UBM pad, and the first side surface of the second line extends farther in the first direction from a center of the UBM pad than the second edge of the redistribution pad extends from the center of the UBM pad.

2. The semiconductor package according to claim 1, wherein the first side surface of the first line, a side surface of the redistribution pad, and the side surface of the UBM pad are disposed along a line oblique to the third direction and the first direction.

3. The semiconductor package according to claim 1, wherein a distance by which a side surface of the redistribution pad extends beyond the side surface of the UBM pad is the same as a minimum width of the first redistribution pattern and the second redistribution pattern.

4. The semiconductor package according to claim 1, wherein a distance by which the first side surface of one of the first line and the second line extends beyond a side surface of the redistribution pad is the same as the minimum width of the first and second redistribution patterns.

5. The semiconductor package according to claim 1, wherein the first redistribution pattern includes a first additional redistribution line disposed between the first line and the second line that is partially aligned with the UBM pad in the third direction.

6. The semiconductor package according to claim 1, further comprising
a third redistribution layer disposed between the first redistribution layer and the second redistribution layer and including a third redistribution pattern and a third dielectric layer;
wherein the third redistribution pattern includes a plurality of second redistribution lines comprising a third line and a fourth line, wherein the first line is aligned with the third line in the third direction, and the second line is aligned with the fourth line in the third direction;
wherein a third side surface of the third line faces opposite in the first direction to a fourth side surface of the third line, and a third side surface of the fourth line faces opposite in the first direction to a fourth side surface of the fourth line; and
wherein the first side surface of the first line extends farther in the first direction from the center of the UBM pad than the third side surface of the third line extends from the center of the UBM pad, and the first side surface of the second line extends farther in the first direction from a center of the UBM pad than the third side surface of the fourth line extends from the center of the UBM pad.

7. The semiconductor package according to claim 6, wherein a distance by which the first side surface of the first line extends in the first direction beyond the third side surface of the third line and a distance by which the first side surface of the second line extends in the first direction beyond the third side surface of the fourth line are the same as a minimum width of the first redistribution pattern, the second redistribution pattern, and the third redistribution pattern.

8. The semiconductor package according to claim 6, wherein the fourth side surface of the third line and the fourth side surface of the fourth line are disposed in partial alignment with the redistribution pad in the third direction, and the third side surface of the third line extends beyond the first edge of the redistribution pad in the first direction, and the third side surface of the fourth line extends beyond the second edge of the redistribution pad.

9. The semiconductor package according to claim 8, wherein a distance by which the third side surface of the third line extends in the first direction beyond the first edge of the redistribution pad and a distance by which the third side surface of the fourth line extends in the first direction beyond the second edge of the redistribution pad are the same as the minimum width of the first redistribution pattern, the second redistribution pattern, and the third redistribution patterns.

10. The semiconductor package according to claim 8, wherein a thermal expansion coefficient of the first redistribution pattern, the second redistribution pattern, and the third redistribution pattern is different from a thermal expansion coefficient of the first dielectric layer, the second dielectric layer, and the third dielectric layer.

11. The semiconductor package according to claim 8, wherein a thermal expansion coefficient of the first redistribution pattern, the second redistribution pattern, and the third redistribution pattern is lower than a thermal expansion coefficient of the first dielectric layer, the second dielectric layer, and the third dielectric layer.

12. The semiconductor package according to claim 8, wherein the first redistribution pattern, the second redistribution pattern, and the third redistribution pattern include metal, and the first dielectric layer, the second dielectric layer, and the third dielectric layer include a polymer-based dielectric material.

13. The semiconductor package according to claim 1, further comprising:
a passivation layer disposed on the second redistribution layer and having an opening that exposes the UBM pad; and
an external connection terminal disposed on the UBM pad.

14. The semiconductor package according to claim 13, wherein an area of the opening is larger than an area of the UBM pad.

15. The semiconductor package according to claim 13, wherein the external connection terminal includes a solder ball.

16. A semiconductor package comprising:
a semiconductor chip;
a connector connected to the semiconductor chip;
a molding member sealing the semiconductor chip and the connector;
a first redistribution layer disposed over the molding member and the connector, and including a first redistribution pattern and a first dielectric layer;
a second redistribution layer disposed on the first redistribution layer and including a second redistribution pattern and a second dielectric layer; and
an under-bump metallurgy (UBM) pad disposed on the second redistribution layer;
wherein the second redistribution pattern includes a redistribution pad that aligns with the UBM pad in a third direction and has an area larger than an area of the UBM pad;
wherein the first redistribution pattern includes a plurality of first redistribution lines comprising a first line and a second line, extending in a second direction perpendicular to a first direction, a first edge of the redistribution pad aligned in the third direction with the first line and a second edge of the redistribution pad aligned in the third direction with the second line;
wherein a first side surface of the first line faces opposite in the first direction to a second side surface of the first line, and a first side surface of the second line faces opposite in the first direction to a second side surface of the second line;
wherein the first side surface of the first line is located farther away from a center of the UBM pad in the first direction than the second side surface of the first line, and the first side surface of the second line is located farther away from a center of the UBM pad in the first direction than the second side surface of the second line; and
wherein a distance between the first side surface of the first line and the first side surface of the second line is larger than a measurement of the redistribution pad in the first direction.

17. The semiconductor package according to claim 16, wherein the measurement in the first direction of the redistribution pad is larger by two times a minimum width of the first redistribution pattern and the second redistribution pattern than the measurement in the first direction of the UBM pad.

18. The semiconductor package according to claim 16, further comprising:
a third redistribution layer disposed between the first redistribution layer and the second redistribution layer and including a third redistribution pattern and a third dielectric layer,
wherein the third redistribution pattern includes a plurality of second redistribution lines comprising a third line and a fourth line, wherein the first line is aligned with the third line in the third direction, and the second line is aligned with the fourth line in the third direction;
wherein a third side surface of the third line faces opposite in the first direction to a fourth side surface of the third line, and a third side surface of the fourth line faces opposite in the first direction to a fourth side surface of the fourth line, the third side surface located farther away from the center of the UBM pad in the first direction than the fourth side surface, and
wherein a distance between the first side surface of the first line and the first side surface of the second line is larger than a distance between the third side surface of the third line and the third side surface of the fourth line.

19. The semiconductor package according to claim 18, wherein the distance between the first side surface of the first line and the first side surface of the second line is larger by two times a minimum width of the first redistribution pattern, the second redistribution pattern, and the third redistribution pattern than the distance between the third side surface of the third line and the third side surface of the fourth line.

20. The semiconductor package according to claim 18, wherein the distance between the third side surface of the third line and the third side surface of the fourth line is larger by two times the minimum width of the first redistribution pattern, the second redistribution pattern, and the third redistribution pattern than a measurement in the first direction of the redistribution pad.

21. The semiconductor package according to claim 18, wherein the first side surface of the first line, the third side surface of the third line, a side surface of the redistribution pad, and a side surface of the UBM pad are disposed along a line oblique to the third direction and the first direction.

22. A semiconductor package comprising:
a semiconductor chip;
a connector connected to the semiconductor chip;
a molding member over the semiconductor chip and the connector;
a first redistribution layer disposed over the molding member and the connector and including a first redistribution pattern and a first dielectric layer;
a second redistribution layer disposed on the first redistribution layer and including a second redistribution pattern and a second dielectric layer; and
an under-bump metallurgy (UBM) pad disposed on the second redistribution layer;
wherein the second redistribution pattern includes a redistribution pad that overlaps the UBM pad in a third direction and has a side surface that extends beyond a side surface of the UBM pad in a first direction;
wherein the first redistribution pattern includes a plurality of first redistribution lines comprising a first line and a second line, wherein the first line and the second line extend in a second direction perpendicular to the first direction and the third direction, wherein a first edge of the redistribution pad overlaps the first line in the third direction and a second edge of the redistribution pad overlaps with the second line in the third direction;
wherein a first side surface of the first line faces in an opposite direction to a second side surface of the first line, and a first side surface of the second line faces in an opposite direction to a second side surface of the second line; and
wherein the second side surface of the first line and the second side surface of the second line overlap the redistribution pad in the third direction, wherein the first side surface of the first line extends farther in the first direction from a center of the UBM pad than the first edge of the redistribution pad extends from the center of the UBM pad, and the first side surface of the second line extends farther in the first direction from a center of the UBM pad than the second edge of the redistribution pad extends from the center of the UBM pad.
